(19) United States
(12) Patent Application Publication
(10) Pub. No.: US 2012/0247536 A1
(43) Pub. Date: Oct. 4, 2012

(54) SOLAR CELL MODULE

(75) Inventors: Shoichi KAWAI, Kuwana-city (JP); Susumu SOBUE, Obu-city (JP); Tomomi TAKAGI, Nagoya-city (JP); DaeGwi KIM, Osaka-city (JP)

(73) Assignees: OSAKA CITY UNIVERSITY, Osaka-city (JP); DENSO CORPORATION, Kariya-city (JP)

(21) Appl. No.: 13/431,157

(22) Filed: Mar. 27, 2012

(30) Foreign Application Priority Data
Mar. 31, 2011 (JP) 2011-79922

(51) Int. Cl. H01L 31/055; B82Y 99/00

(52) U.S. Cl. 136/247; 977/948

(57) ABSTRACT

A solar cell module includes a plurality of solar cells, a wavelength conversion layer, and a translucent protection plate. The solar cells are arranged in a plane direction. The wavelength conversion layer is disposed at a light-receiving side of the solar cells to convert a wavelength of light. The protection plate is disposed at a light-receiving side of the wavelength conversion layer. The protection plate has an inclined reflection surface at an end thereof to reflect light, which travels inside of the protection plate to the end of the protection plate, toward the solar cells.

### CROSS REFERENCE TO RELATED APPLICATION

This application is based on Japanese Patent Application No. 2011-79922 filed on Mar. 31, 2011, the disclosure of which is incorporated herein by reference.

### TECHNICAL FIELD

The present disclosure relates to a solar cell module.

### BACKGROUND

A solar cell module has been known as a device generating electric power from light such as solar light. In a general solar cell module, power generation efficiency is different depending on a wavelength range of light. That is, a wavelength range of light that produces maximum power generation efficiency is limited to a certain wavelength range depending on characteristics of materials of a solar cell. Therefore, the wavelength range of light to be effectively used in the solar cell is likely to be narrowed as an increase in power generation efficiency is desired.

As a technology that can adapt to a wide range of wavelength of light, for example, a multilayer solar battery, such as a tandem solar battery, has been known. In the multiplayer solar battery, thin film solar cells, which are made of different materials to absorb different wavelengths of light, are stacked so as to produce maximum power generation efficiency at different wavelengths of light, that is, to expand the wavelength range of light to be effectively used.

JP08-4147B2 describes to employ a wavelength conversion plate, such as a fluorescence optical plate, or a glass plate on which a fluorescence dye is deposited so as to convert a wavelength of light that produces low power generation efficiency into a wavelength of light that produces high power generation efficiency. The light is introduced into a solar cell after the wavelength of the light is converted into the effective wavelength by the wavelength conversion plate.

JP57-95675A describes a solar cell module in which solar cells are attached to edge surfaces of a wavelength conversion plate. In the described solar cell module, light is totally reflected in the wavelength conversion plate to be introduced into the solar cells.

### SUMMARY

In the multilayer solar battery described above, the number of solar cells to be stacked is limited, as well as manufacturing costs are likely to increase due to a stacking structure. Also, an expensive material such as Ge board is used.

In a solar cell module using the wavelength conversion plate or the like, approximately 70% or more of the light whose wavelength has been converted is focused on edge surfaces of the wavelength conversion plate or the like. Therefore, the amount of light introduced into the solar cell is likely to be insufficient.

In the solar cell module having the solar cells attached to the edge surfaces of the wavelength conversion plate as described in JP57-95675A, the amount of light introduced into the solar cells can be increased. However, it is difficult to attach the solar cells to the thin edge surfaces, resulting in an increase in the manufacturing costs.

To solve the above matters, JP11-345993A describes to arrange wavelength conversion films made of an inorganic fluorescence material on a light conversion film board. The wavelength conversion films are arranged separate from each other as islands. Further, edge surfaces of each wavelength conversion films are inclined, and a reflection film is disposed along the inclined edge surfaces.

In such a structure, however, it is difficult to improve power generation efficiency because shades are formed on the solar cells located behind the wavelength conversion films by the ends of the wavelength conversion films.

It is an object of the present disclosure to provide a solar cell module with improved power generation efficiency.

According to an aspect, a solar cell module includes a plurality of solar cells, a wavelength conversion layer, and a translucent protection plate. The solar cells are arranged in a plane direction. The wavelength conversion layer is disposed at a light-receiving side of the solar cells to convert a wavelength of light. The protection plate is disposed at a light-receiving side of the wavelength conversion layer. The protection plate has an inclined reflection surface at an end thereof to reflect light, which travels inside of the protection plate to the end of the protection plate, toward the solar cells.

In such a structure, of the light entering the wavelength conversion layer through the protection plate, light having a predetermined wavelength or more is directly introduced into the solar cells. On the other hand, light having a wavelength less than the predetermined wavelength is converted in the wavelength conversion layer into light having the predetermined wavelength or more, and then introduced into the solar cells. Further, although a part of the converted light is reflected into the protection plate, the part of the converted light is totally reflected within the protection plate and focused on the end of the protection plate. The focused light is reflected by the inclined reflection surface of the protection plate, and introduced into the solar cells through the wavelength conversion layer.

Accordingly, the light having a wavelength less than the predetermined wavelength can be converted into the light having a wavelength greater than the predetermined wavelength, which can be effectively used in the solar cells. Further, the light reflected toward the protection plate is introduced into the solar cells by being reflected at the inclined reflection surface. As such, the light is effectively used, and power generation efficiency of the solar cell module is improved. Also, the solar cell module having the above described structure can be easily manufactured at reduced costs.

### BRIEF DESCRIPTION OF THE DRAWINGS

The above and other objects, features and advantages of the present disclosure will become more apparent from the following detailed description made with reference to the accompanying drawings, in which like parts are designated by like reference numbers and in which:

FIG. 1 is a diagram illustrating a cross-sectional view of a solar cell module according to a first embodiment;

FIG. 2 is a diagram illustrating a plan view of the solar cell module according to the first embodiment;

FIG. 3 is a diagram illustrating a spectrum sensitivity characteristic of the solar cell module according to the first embodiment;

FIG. 4 is a diagram illustrating a cross-sectional view of a solar cell module according to a second embodiment; and

FIG. 5 is a diagram illustrating a cross-sectional view of a solar cell module according to a third embodiment.

### DETAILED DESCRIPTION

Hereinafter, exemplary embodiments will be described.

In an embodiment, a solar cell module includes a plurality of solar cells, a wavelength conversion layer, and a protection plate. The solar cells are arranged in a plane direction. The wavelength conversion layer is disposed at a light-receiving side of the solar cells to convert a wavelength of light. The protection plate has translucency, that is, is made of a material that allows light to transmit. The protection plate is disposed at a light-receiving side of the wavelength conversion layer. The protection plate has an inclined reflection surface at an end thereof to reflect light, which travels inside of the protection plate to the end of the protection plate, toward the solar cells.

In such a structure, of the light such as solar light entering the wavelength conversion layer through the protection plate, light having a predetermined wavelength, such as visible light having a wavelength of 400 nanometers (nm) or more, is directly introduced into the solar cells without being converted by the wavelength conversion layer. On the other hand, light having a predetermined wavelength, such as ultraviolet light having a wavelength less than 400 nm, is converted into light having a longer wavelength, such as visible light having a wavelength of 500 nm or more, and then introduced into the solar cells.

Further, although a part of the converted light is reflected into the protection plate, the part of the converted light is totally reflected in the protection plate and focused on the end of the protection plate. The light focused on the end of the protection plate is reflected by the inclined reflection surface, and is introduced into the solar cells through the wavelength conversion layer.

Accordingly, light having a wavelength less than the predetermined wavelength, such as ultraviolet light having a shorter wavelength, can be converted into light having a wavelength equal to or greater than the predetermined wavelength, which can be effectively used in the solar cells. Further, the light reflected toward the protection plate is introduced into the solar cells by being reflected at the inclined reflection surfaces. As such, light entering the solar cell module is effectively used, and power generation efficiency improves.

In addition, it is less likely that a shade will be formed on the light-receiving side of the solar cells as a conventional device. Therefore, the light passing through the wavelength conversion layer can be effectively introduced into the solar cells. As such, power generation efficiency of the solar cell module improves. Also, the solar cell module having the above described structure can be easily manufactured at reduced costs.

For example, the inclined reflection surface is inclined at an angle greater than 90 degrees and less than 180 degrees relative to a surface of the protection plate. In a case where the inclined reflection surface is inclined at an angle greater than 125 degrees and less than 145 degrees relative to the surface of the protection plate, the light reflection effect further improves.

For example, the solar cell is provided by a thin film Si cell, CIGS cell, CdTe cell, GaAs cell, a dye sensitized cell, an organic dye cell, or the like.

In an embodiment, a reflection layer is disposed on the inclined reflection surface of the protection plate. In such a structure, light reaching the inclined reflection plate can be efficiently reflected toward the solar cells. For example, the reflection layer is provided by a reflective tape made of aluminum. Also, the reflection layer may be formed by aluminum deposition or spattering.

In an embodiment, the wavelength conversion layer converts light having a wavelength less than 500 nm into light having a wavelength of 500 nm or more. For example, in a Si crystal solar cell, light having the wavelength of 500 nm or more can be effectively converted into electricity. Therefore, it is advantageous to convert a wavelength of light into the wavelength that is effective to the solar cells in order to improve power generation efficiency.

In an embodiment, the wavelength conversion layer is provided by a wavelength conversion film. For example, the wavelength conversion film is made by adding a material that carries out wavelength conversion in a base material. As the base material of the film, for example, a translucent silicone resin is used. In the present disclosure, “translucent” means a property that allows light to transmit.

In place of the wavelength conversion film, a glass plate, a resin plate, a deposition layer of a wavelength conversion material can be used. As examples of the glass, silica and boron oxide-base glass are used. As examples of the resin, acryl, polycarbonate and the like are used.

In an embodiment, the solar cells are sealed with a translucent sealing material, and the wavelength conversion layer is disposed along a layer portion of the sealing material disposed on a light-receiving side of the solar cells. In such a structure, the solar cells can be easily and securely fixed by the sealing material.

In an embodiment, the wavelength conversion layer is tightly in contact with the surfaces of the solar cells at the light-receiving side, and the solar cells and the wavelength conversion layer are sealed together with a translucent sealing material. In such a structure, since the wavelength conversion layer is tightly in contact with the light-receiving side of the solar cells, external light can be effectively introduced toward the solar cells.

In an embodiment, the wavelength conversion layer is tightly in contact with the surfaces of the solar cells at the light-receiving side, and the protection plate is tightly in contact with the surface of the wavelength conversion layer at the light-receiving side. In such a structure, since the solar cells, the wavelength conversion layer and the protection plate are tightly in contact with each other, external light can be effectively introduced toward the solar cells.

In an embodiment, the wavelength conversion layer contains an organic fluorescence material or an inorganic fluorescence material. As examples of the organic fluorescence material, perylene, naphthalimide, tris-(8-hydroxyquinoline)aluminum (Alq3) and the like are adopted. As examples of the inorganic fluorescence material, Y2O3:Eu, ZnS:Mn, ZnSe:Mn and the like are adopted.

In an embodiment, nano particles that absorb light having a predetermined wavelength are dispersed in the wavelength conversion layer, and the nano particles contains an element as a luminescence center that emits light having a wavelength greater than the wavelength absorbed.

Therefore, light having a shorter wavelength, such as ultraviolet light, can be converted into light having a longer wavelength corresponding to the kind of element as the luminescent center. For example, light having a shorter wavelength such as ultraviolet light, which is not effectively used in the solar cells such as Si solar cells can be converted into light having a longer wavelength, which can be effectively used in the solar cells. Therefore, power generation efficiency of the solar cell module improves. It is to be noted that the nano particles are particles having the characteristic of the quantum dot of a nano level (for example, particle diameter of 1 to 20 nm).

For example, the nano particle is made of any one of zinc selenide (ZnSe), cadmium selenide (CdSe), cadmium sulfide (CdS), cadmium zinc selenide (ZnCdSe), and zinc sulfide (ZnS).

For example, the element as the luminescence center is any one of manganese (Mn), europium (Eu), ytterbium (Yb), terbium (Tb), antimony (Sb), silver (Ag), copper (Cu), gold (Au), and aluminum (Al).

Exemplary embodiments of the solar cell module will be described further in detail as first through fourth embodiments with reference to the drawings.

### First Embodiment

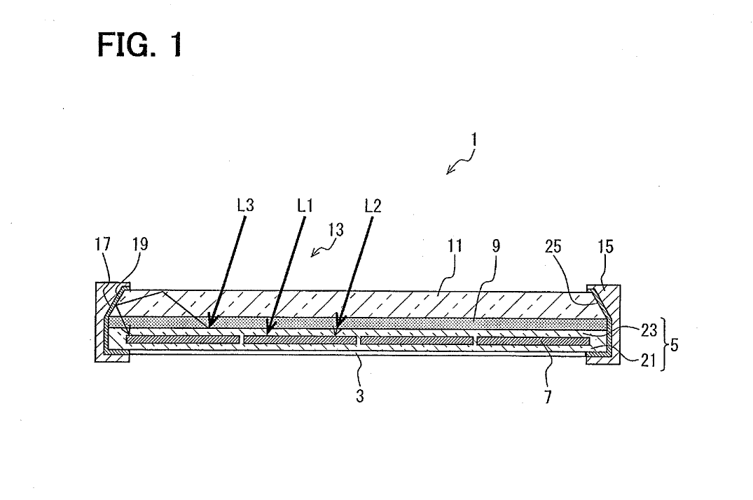

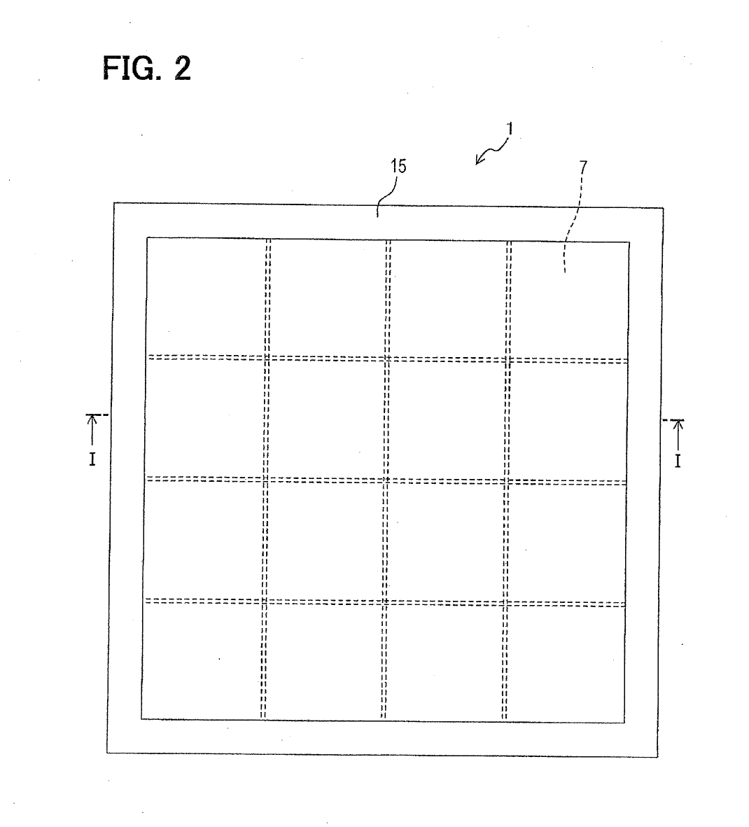

Referring to FIGS. 1 and 2, first, a schematic structure of a solar cell module 1 according to the first embodiment will be described. FIG. 1 is a diagram illustrating a cross-sectional view of a solar cell module taken along a line I-I in FIG. 2.

The solar cell module 1 has a generally plate shape. For example, the solar cell module 1 has a square planer shape. The solar cell module 1 generally includes multiple solar cells 7, a wavelength conversion layer 9, and a transparent protection glass 11. The multiple solar cells 7 are sealed in a transparent sealing layer 5 and disposed on a front surface of a back sheet 3, that is, at a light-receiving side of the back sheet 3. The front surface of the back sheet 3 corresponds to an upper surface in FIG. 1. The wavelength conversion layer 9 is disposed at a light-receiving side of the solar cells 7 to convert a wavelength of light. The protection glass 11 is disposed at a light-receiving side of the wavelength conversion layer 9.

The back sheet 3, the sealing layer 5, the solar cells 7, the wavelength conversion layer 9 and the protection glass 11 constitute a stacked body 13 having a square planer shape. The stacked body 13 is disposed in a square frame 15.

The frame 15 has a recessed portion on its inner side surface 17. A lower portion of the inner side surface 17 is perpendicular to a thickness direction in which a thickness of the frame 15 is measured, such as in an up and down direction in FIG. 1. An upper portion of the inner side surface 17 is inclined inwardly as a function of distance from the lower portion. A reflection layer 19 is formed on the inner side surface 17 for reflecting light inside of the frame 15.

Hereinafter, a structure of each component will be described.

The back sheet 3 is a plate member made of polyethylene terephthalate, for example.

The sealing layer 5 includes a lower sealing layer portion 21 disposed under the solar cells 7 and an upper sealing layer portion 23 disposed above the solar cells 7. For example, the sealing layer 5 is made of an ethylene vinyl acetate polymer or a silicone resin.

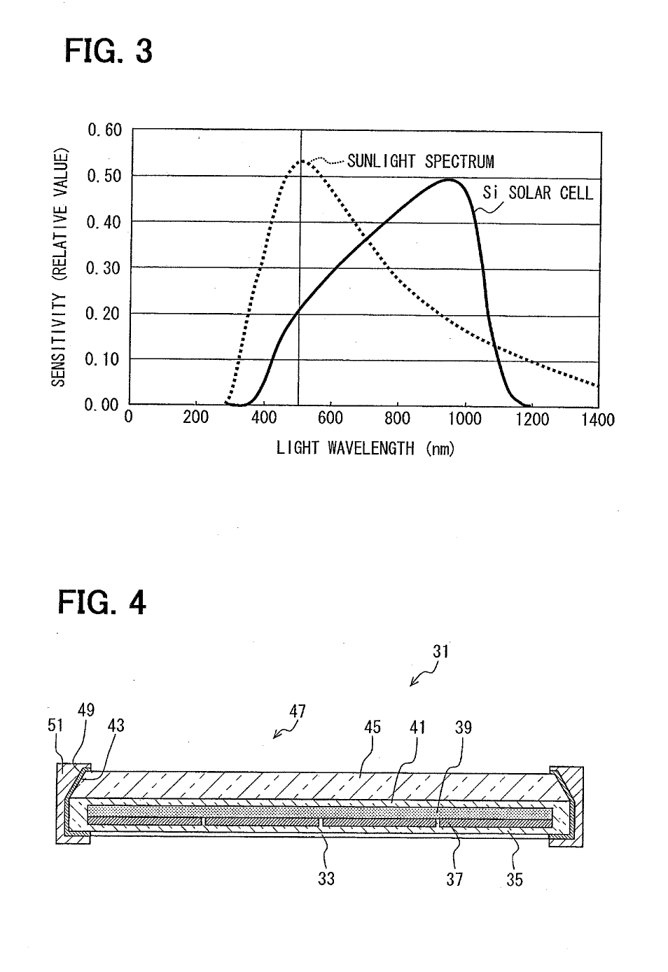

The solar cell 7 has a square planar shape. For example, the solar cell 7 is a single crystal silicon solar cell (Si solar cell) having a band gap of 1.1 eV. The solar cell 7 has a spectrum characteristic as shown in FIG. 3. The solar cells 7 are arranged in a matrix along a plane direction, such as in four rows by four lines as shown in FIG. 2, and are electrically connected to each other.

The protection glass 11 is provided as an example of a translucent protection plate. For example, the protection glass 11 is a transparent plate, such as a white plate glass. The protection glass 11 has an inclined reflection surface 25 at an end.

An edge surface of the protection glass 11 is inclined to provide the inclined reflection surface 25. The inclined reflection surface 25 is inclined inwardly toward an upper edge thereof. The inclined reflection surface 25 is formed over an entire circumference of the protection glass 11.

An angle of inclination of the inclined reflection surface 25 with respect to a plane surface of the protection glass 11 is greater than 90 degrees and less than 180 degrees. For example, the angle of inclination of the inclined reflection surface 25 is greater than 125 degrees and less than 145 degrees.

The reflection layer 19 is provided by a reflective tape of aluminum or the like, for example. For example, the reflection layer 19 is made by aluminum evaporation, spattering or the like.

The wavelength conversion layer 9 is provided by a silicone resin film in which nano particles as quantum dots are evenly dispersed. The wavelength conversion layer 9 has a translucency that allows 90% or more of light having a wavelength of 500 nm or more to transmit.

The nano particle has a nano-sized diameter, such as in a range between 1 nm and 20 nm, and contains an element (dopant) as a luminescent center therein. The nano particle absorbs light having a wavelength of less than 500 nm, and emits light having a wavelength of 500 nm or more, such as 900 nm or more.

For example, the nano particle that has a particle diameter of 3 nm and is made of zinc selenide (ZnSe) is used. Also, the nano particle contains manganese (Mn) therein as the dopant providing the luminescence center, for example. In such a case, the nano particle absorbs light such as ultraviolet light having a wavelength of 400 nm or less, and emits light having a wavelength of 585 nm.

As the nano particles, various inorganic materials can be adopted. For example, cadmium selenide (CdSe), cadmium sulfide (CaS), cadmium zinc selenide (ZnCdSe), zinc sulfide (ZnS) and the like are used, in addition to zinc selenide (ZnSe). As the element of the luminescence center, for example, europium (Eu) having an emission wavelength of 690 nm, copper (Cu) having an emission wavelength of 550 nm, ytterbium (Yb) having an emission wavelength of 900 nm, and the like are used depending on the emission wavelength, in addition to manganese (Mn).

In addition, the wavelength conversion layer 9 can be provided using various known materials that can convert light having a wavelength that is not effectively used in the solar cells 7 into light having a wavelength that is effectively used in the solar cells 7.

Next, a manufacturing method of the solar cell module 1 will be described.

<Composition of Nano Particle Solution>

First, the ZnSe nano particle doped with Mn is produced with a hydrothermal synthesis method using a zinc (Zn) ion source, a selenium (Se) ion source, and a manganese (Mn) ion source.

Specifically, a solution 1 is firstly produced by blending the Zn ion source and organic base ligand (N-acetylcysteine: NAC) at a molar ratio of 1:5. Also, a solution 2 is produced by blending the Mn ion source and the organic base ligand at a molar ratio of 1:1.

Next, the solution 1 and the solution 2 are mixed at a ratio of 99:1 maintaining a pH in a range between 1.5 and 2 to produce a solution 3 having a Mn concentration of 1%. Then, sodium hydroxide (NaOH) is added to the solution 3 to produce a solution 4 with a pH of 8.5.

Further, the Se ion source is added to the solution 4 to produce a precursor solution 5 of ZnMnSe. The solution 5 preferably has a pH of approximately 10.5.

Then, 10 ml of the solution 5 is put in a pressure container, and heated for a predetermined time, such as few minutes to approximately thirty minutes, at 200 degrees Celsius and at a pressure of 2 atmospheres to synthesize ZnSe:Mn nano particles (nanoclusters) having a particle diameter of few nanometers to approximately 8 nanometers.

<Binder Mixture>

A silicone resin as a binder is added to the nano particle solution synthesized in the above described manner to produce a mixed resin material in a paste state.

<Film Formation by Printing>

The mixed resin material is deposited on a base by a screen printing to form a printed layer. The printed layer is dried to form a film containing the nano particles as the wavelength conversion layer 9.

<Fabrication of the Solar Cell Module 1>

The back sheet 3, the lower sealing layer 21, the solar cells 7, the upper sealing layer 23, the film as the wavelength conversion layer 9, the protection glass 11 are laid in a predetermined order, and heated under high pressure to produce the stacked body 13 by a thermosetting sealing. After attaching the reflection tape to the periphery of the stacked body 13, the stacked body 13 is fitted in the frame 15. In this way, the solar cell module 1 is produced.

Next, advantageous effects of the present embodiment will be described.

In the solar cell module 1 of the present embodiment, light (e.g., solar light) enters the wavelength conversion layer 9 through the protection glass 11 from the top in FIG. 1. Of the light entering the wavelength conversion layer 9, light (visible light) having a wavelength of 400 nm or more directly enters the solar cells 7 without being converted in wavelength. (See an arrow L1 in FIG. 1).

Of the light entering the wavelength conversion layer 9, light (e.g., ultraviolet light) having a wavelength of less than 400 nm is absorbed by the nano particles, and converted to light having a wavelength of 585 nm. The light converted through the wavelength conversion layer 9 enters the solar cells 7 through the upper sealing layer 23. (See an arrow L2 in FIG. 1.)

Further, a part of the light converted through the wavelength conversion layer 9 is reflected into the protection glass 11. In the protection glass 11, the part of the converted light is totally reflected and focused on a side end of the protection glass 11. The focused light is reflected by the reflection layer 19, and introduced into the solar cells 7 through the wavelength conversion layer 9. (See an arrow L3 in FIG. 1)

As described above, in the present embodiment, light in a shorter wavelength range such as the ultraviolet light is converted into light in a longer wavelength range that is effectively used in the solar cells 7, and the light reflected toward the protection glass 11 can be introduced to the solar cells 7 by being reflected at the reflection layer 19. Therefore, light entering the solar cell module 1 can be effectively used, resulting in the improvement of power generation efficiency.

In addition, it is less likely that shade will be formed on the light-receiving side of the solar cells 7. Therefore, the light passing through the wavelength conversion layer 9 can be effectively introduced into the solar cells 7. Accordingly, in the solar cell module 1 of the present embodiment, the power generation efficiency is improved, and is easily manufactured while saving the manufacturing costs.

### Second Embodiment

A second embodiment will be described with reference to FIG. 4. Hereinafter, structures different from the first embodiment will be mainly described.

As shown in FIG. 4, a solar cell module 3 of the present embodiment has a stacked body 47 including a back sheet 33, a lower sealing layer 35, solar cells 37, a wavelength conversion layer 39, an upper sealing layer 41 and a protection glass 45. The protection glass 45 has an inclined reflection surface 43 at an end. The back sheet 33, the lower sealing layer 35, the solar cells 37, the wavelength conversion layer 39, the upper sealing layer 41 and the protection glass 45 are disposed on top of the other in this order.

The stacked body 47 has a reflection layer 49 along its edge surface. The stacked body 47 is disposed in a rectangular frame 51. The wavelength conversion layer 39 is tightly in contact with the surfaces of the solar cells 37 at the light-receiving side, and the solar cells 37 and the wavelength conversion layer 39 are sealed in between the lower sealing layer 35 and the upper sealing layer 41.

Also in the present embodiment, the advantageous effects similar to the first embodiment can be achieved. In addition, since the solar cells 37 and the wavelength conversion layer 39 are tightly in contact with each other, light can be further effectively introduced into the solar cells 37.

### Third Embodiment

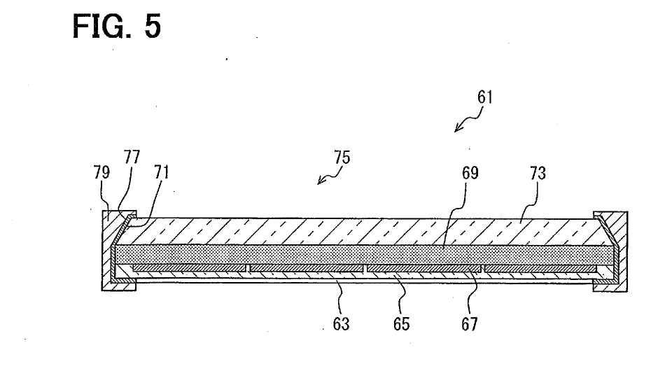

A third embodiment will be described with reference to FIG. 5. Hereinafter, structure different from the first embodiment will be mainly described.

As shown in FIG. 5, a solar cell module 61 of the present embodiment has a stacked body 75 including a back sheet 63, a sealing layer 65, solar cells 67, a wavelength conversion layer 69, and a protection glass 73. The protection glass 73 has an inclined reflection surface 71 at an end. The back sheet 63, the sealing layer 65, the solar cells 67, the wavelength conversion layer 69, and the protection glass 45 are disposed on top of the other in this order.

The stacked body 75 has a reflection layer 77 along its edge surface. The stacked body 75 is disposed in a rectangular frame 79. The wavelength conversion layer 69 is tightly in contact with the surfaces of the solar cells 67 at the light-receiving side, and the protection glass 73 is tightly in contact with the surface of the wavelength conversion layer 69 at the light-receiving side.

Also in the present embodiment, the advantageous effects similar to the first embodiment can be achieved. In addition, since the solar cells 67, the wavelength conversion layer 69 and the protection glass 73 are tightly in contact with each other, light can be further effectively introduced into the solar cells 67.

### Fourth Embodiment

A fourth embodiment will be hereinafter described. Structures different from those of the first embodiment will be mainly described.

In the present embodiment, the wavelength conversion layer is made of a material different from those of the first through third embodiments.

For example, the wavelength conversion layer is provided by a wavelength conversion plate such as a fluorescence glass (e.g., LUMILASS-G9, SUMITA Optical glass, Inc.). The wavelength conversion plate is made of a Tb added fluorescence glass (e.g., B₂O₃.CaO.SiO₂.La₂O₃.Tb³⁺). The wavelength conversion plate absorbs light in an ultraviolet region where a wavelength of light is 400 nm or less of light, and produces fluorescence with a wavelength of 545 nm.

As another example of the wavelength conversion layer, a wavelength conversion optical plate can be used. For example, a transparent acrylic plate (PMMA) in which an organic fluorescence material such as an organic fluorescent dye (e.g., LUMOGEN®, BASF Corporation) is mixed is used.

As further another example of the wavelength conversion layer, a translucent wavelength conversion layer can be formed by depositing an organic fluorescent dye on a surface of the protection glass, the surface facing the solar cells, for example. The organic fluorescent dye is, for example, provided by Pt (TPBP). The organic fluorescent dye absorbs light at 600 nm or less, and emits light at approximately 800 nm. In such a case, therefore, light in a wavelength range that produces a larger amount of power can be used in the solar cell module having the single crystal silicon solar cells.

Also in the present embodiment, the advantageous effects similar to those of the first embodiment can be achieved.

The exemplary embodiments are described hereinabove. However, the present disclosure is not limited to the above described exemplary embodiments, but may be implemented in any other ways without departing from the spirit of claims.

(1) For example, an antireflection film may be formed on the surface of the protection glass in the solar cell module of the above described embodiments. The antireflection film is, for example, made of TiO₂ film and SiO₂ film, and such films are alternately stacked by a vacuum deposition technique.

(2) The solar cell module of the above described embodiments may be adaptable also to light other than solar light.

While the present disclosure has been described with reference to exemplary embodiments thereof, it is to be understood that the disclosure is not limited to the above described exemplary embodiments and constructions. The present disclosure is intended to cover various modification and equivalent arrangements. In addition, while the various combinations and configurations, which are preferred, other combinations and configurations, including more, less or only a single element, are also within the spirit and scope of the present disclosure.

What is claimed is:

1. A solar cell module comprising:
a plurality of solar cells arranged in a plane direction;
a wavelength conversion layer disposed at a light-receiving side of the solar cells; and
a translucent protection plate disposed at a light-receiving side of the wavelength conversion layer, the protection plate having an inclined reflection surface at an end thereof to reflect light, which travels inside of the protection plate to the end of the protection plate, toward the solar cells.

2. The solar cell module according to claim 1, further comprising a reflection layer disposed on the inclined reflection surface.

3. The solar cell module according to claim 1, wherein the wavelength conversion layer is configured to convert light having a wavelength less than 500 nanometers into light having a wavelength of 500 nanometers or more.

4. The solar cell module according to claim 1, wherein the wavelength conversion layer is provided by a wavelength conversion film.

5. The solar cell module according to claim 1, further comprising:
a translucent sealing member sealing a periphery of the solar cells, wherein
the sealing member includes a sealing layer portion formed along surfaces of the solar cells at the light-receiving side of the solar cells, and
the wavelength conversion layer is disposed along the sealing layer portion of the sealing member.

6. The solar cell module according to claim 1, wherein
the wavelength conversion layer is tightly in contact with surfaces of the solar cells at the light-receiving side of the solar cells, the solar cell module further comprising:
a translucent sealing member sealing a periphery of the solar cells and the wavelength protection layer.

7. The solar cell module according to claim 1, wherein
the wavelength conversion layer is tightly in contact with surfaces of the solar cells at the light-receiving side of the solar cells, and
the protection plate is tightly in contact with a surface of the wavelength conversion layer at the light-receiving side of the wavelength conversion layer.

8. The solar cell module according to claim 1, wherein the wavelength conversion layer contains one of an organic fluorescence material and an inorganic fluorescence material as a material converting a wavelength of light.

9. The solar cell module according to claim 8, wherein
the wavelength conversion layer contains a nano particle that absorbs light having a predetermined wavelength,
the nano particle is dispersed in the wavelength conversion layer, and
the nano particle contains an element as a luminescence center that emits light having a wavelength longer than the predetermined wavelength.

10. The solar cell module according to claim 9, wherein the nano particle is made of at least one of zinc selenide, cadmium selenide, cadmium sulfide, cadmium zinc selenide, and zinc sulfide.

11. The solar cell module according to claim 9, wherein the element as the luminescence center is at least one of manganese, europium, ytterbium, terbium, antimony, silver, copper, gold, and aluminum.
